(19) United States
(12) Patent Application Publication
(10) Pub. No.: US 2026/0190688 A1
(43) Pub. Date: Jul. 2, 2026

(54) Display Device

(71) Applicant: LG Display Co., Ltd., Seoul (KR)

(72) Inventors: Joonyoung Kwon, Paju-si (KR); Kyeongseob Kwon, Paju-si (KR)

(21) Appl. No.: 19/217,158

(22) Filed: May 23, 2025

(30) Foreign Application Priority Data
Dec. 30, 2024 (KR) 10-2024-0200408

(51) Int. Cl. H10K 59/131; G09G 3/3233

(52) U.S. Cl. CPC H10K 59/131; G09G 3/3233; G09G 2300/0426; G09G 2300/0819; G09G 2300/0842; G09G 2300/0861; G09G 2330/04; G09G 2330/08; G09G 2330/12

(57) ABSTRACT

The present disclosure relates to a display device capable of repairing data line open defects. In the display device according to one embodiment, when an open defect occurs in a first data line, the open portion of the first data line and adjacent first and second redundancy lines and the first low-potential power line are each divided into a plurality of segments. The divided first and second redundancy lines, the divided first low-potential power line, and the divided data line are electrically connected to one another through respective repair parts at respective intersections, thereby enabling repair of the open defect in the first data line.

### CROSS-REFERENCE TO RELATED APPLICATION

This application claims priority to Republic of Korea Patent Application No. 10-2024-0200408, filed on Dec. 30, 2024, which is hereby incorporated by reference in its entirety.

### BACKGROUND

### Field of Technology

The present disclosure relates to a display device capable of repairing an open defect in a data line.

### Discussion of the Related Art

Electroluminescence display devices utilize self-luminous elements that emit light through the recombination of electrons and holes in an organic light emitting layer, and have the advantages of high brightness, low operating voltage, ultra-thin film formation, and freedom of shape implementation.

The electroluminescence device may include a display panel that displays an image through a pixel matrix, and a driving circuit that drives the display panel. Each of the pixels constituting the pixel matrix may be independently driven by a plurality of thin film transistors.

In the electroluminescence display device, a defect may occur in which a data line disposed in the display area is opened. As a result, a panel defect may occur where the pixels connected to the defective data line are darkened in a line shape.

### SUMMARY

Accordingly, the present disclosure is directed to providing a display device that substantially obviate one or more problems due to limitations and disadvantages of the related art.

In one embodiment, the present disclosure provides a display device capable of repairing an open defect in a data line.

Additional advantages and features of the disclosure will be set forth in part in the description which follows and in part will become apparent to those having ordinary skill in the art upon examination of the following or may be learned from practice of the disclosure. The technical benefits and other advantages of the disclosure may be realized and attained by the structure particularly pointed out in the written description and claims hereof as well as the appended drawings.

To achieve these and other benefits and in accordance with the purpose of the disclosure, as embodied and broadly described herein, the present disclosure provides a display device including a plurality of data lines connected to the plurality of subpixels, a plurality of low-potential power lines connected to the plurality of subpixels, and a plurality of redundancy lines crossing the plurality of data lines and the plurality of low-potential power lines, wherein the plurality of subpixels include a first subpixel and a second subpixel disposed adjacent in a first direction and connected to a first data line extending in the first direction, wherein the plurality of low-potential power lines include a first low-potential power line disposed parallel to the first data line in a second direction, wherein the plurality of redundancy lines extend in the second direction and include a first redundancy line and a second redundancy line respectively passing through the first subpixel and the second subpixel, wherein the second redundancy line intersects the first data line at a first intersection and intersects the first low-potential power line at a second intersection, and wherein the first redundancy line intersects the first low-potential power line at a third intersection and intersects the first data line at a fourth intersection.

When the first data line is opened between the first intersection and the fourth intersection, the first data line is divided into a 1-1 data line and a 1-2 data line, the second redundancy line is divided into a 2-1 redundancy line, a 2-2 redundancy line, and a 2-3 redundancy line by first and second cutting parts, the first redundancy line is divided into a 1-1 redundancy line, a 1-2 redundancy line, and a 1-3 redundancy line by third and fourth cutting parts, the first low-voltage power line is divided into a 1-1 low-potential power line, a 1-2 low-potential power line, and a 1-3 low-potential power line by fifth and sixth cutting parts, the 2-2 redundancy line is connected to the 1-2 data line via a first repair part at the first intersection, and connected to the 1-2 low-potential power line via a second repair part at the second intersection, and the 1-2 redundancy line is connected to the 1-2 low-potential power line via a third repair part at the third intersection, and connected to the 1-2 data line via a fourth repair part at the fourth intersection.

It is to be understood that both the foregoing general description and the following detailed description of the present disclosure are exemplary and explanatory and are intended to provide further explanation of the disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a drawing schematically illustrating the configuration of a display device according to one embodiment of the present disclosure.

FIG. 2 is a drawing illustrating a repair structure of a data line in a display device according to one embodiment of the present disclosure.

FIG. 3 is a drawing illustrating a layout structure of pixel circuits including a repair structure of a data line in a display device according to one embodiment of the present disclosure.

FIGS. 4, 5A, 5B, 6A, 6B, 7A, 7B, 8A, 8B, 9A, 9B, 10A, and 10B are drawings illustrating the layout of the pixel circuits illustrated in FIG. 3 according to the mask process according to one embodiment of the present disclosure.

FIG. 11 is a drawing illustrating a repair process of a display device according to one embodiment of the present disclosure.

FIG. 12 is a drawing illustrating a repair process of a display device according to one embodiment of the present disclosure.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present disclosure are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

Hereinafter, the aspect of the present disclosure will be described with reference to the accompanying drawings. Since a scale of each of elements shown in the accompanying drawings is different from an actual scale for convenience of description, the present disclosure is not limited to the shown scale. Further, all the components of each display apparatus, display device, and display panel according to all aspects of the present disclosure are operatively coupled and configured.

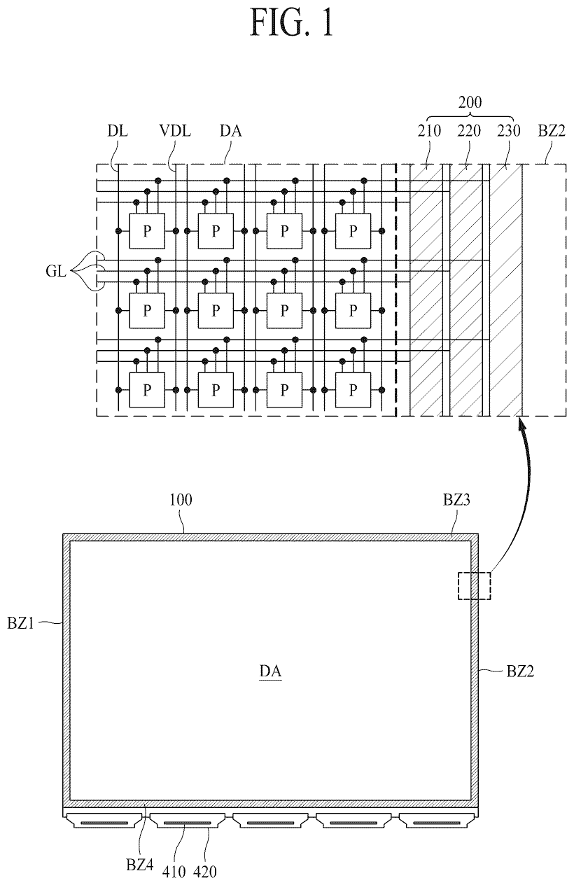

FIG. 1 is a block diagram schematically illustrating the configuration of a display device according to one embodiment of the present disclosure.

The display device according to one embodiment may be an electroluminescence display device including an organic light emitting diode (OLED) display device, a quantum-dot light emitting diode display device, or an inorganic light emitting diode display device. The display device according to one embodiment may be a micro light emitting diode display device.

Referring to FIG. 1, the display device may include a display panel 100, a gate driving circuit 200 built into the display panel 100, and a data driving circuit 410 connected to the display panel 100. The gate driving circuit 200 and the data driving circuit 410 may be expressed as a driving circuit.

The display panel 100 may be a rigid display panel or a flexible display panel capable of changing shape, such as a foldable, bendable, rollable, or stretchable display panel.

The display panel 100 may display an image through a display area DA in which a plurality of subpixels P are arranged in a matrix form. The subpixel P may be any one of a red subpixel that emits red light, a green subpixel that emits green light, a blue subpixel that emits blue light, and a white subpixel that emits white light. A unit pixel may include at least two subpixels including different emission colors. Each subpixel P may include a light emitting element and a pixel circuit that independently drives the light emitting element, and the pixel circuit may include a plurality of thin film transistors and a capacitor.

The display panel 100 may include a plurality of wires including a plurality of data lines DL, a plurality of gate lines GL, a plurality of high-potential power lines VDL, a plurality of low-potential power lines, a plurality of redundancy lines, and other signal lines connected to the plurality of subpixels P.

The display panel 100 according to one embodiment may further include a touch sensor screen disposed in the display area DA to sense a user's touch.

The display panel 100 according to one embodiment may be a touch display panel having a touch sensor array built in. For example, the display panel 100 according to one embodiment may include a pixel array, an encapsulation layer, and a touch sensor array. The pixel array may include a circuit element layer including a plurality of transistors disposed on a substrate and a light emitting element layer including a plurality of light emitting elements disposed on the circuit element layer. The encapsulation layer may be disposed to seal the light emitting element layer on the pixel array. The touch sensor array may include a plurality of touch electrodes disposed on the encapsulation layer. The display panel 100 according to one embodiment may further include an optical film, an optical clear adhesive (OCA), a cover substrate, a protective film, etc. which are sequentially disposed on the touch sensor array. The display panel 100 according to one embodiment may further include a color filter array including a color filter and a black matrix disposed between the touch sensor array and the optical film.

The gate driving circuit 200 may be disposed in at least one of the bezel areas BZ1 to BZ2 located at the outer portion surrounding the display area DA of the display panel 100. For example, the gate driving circuit 200 may be disposed in at least one of the first and second bezel areas BZ1, BZ2 facing each other with the display area DA interposed therebetween. The gate driving circuit 200 may be built into the display panel 100 in the form of a gate in panel (GIP) formed together with thin film transistors of the display area DA.

The gate driving circuit 200 may include first and second scan driving circuits 210 and 220, and a light emission control driving circuit 230 configured to drive a plurality of gate lines GL. The first scan driving circuit 210 may include a plurality of first scan stages configured to supply a first scan signal to each of a first group of gate lines among the plurality of gate lines GL. The second scan driving circuit 220 may include a plurality of second scan stages configured to supply a second scan signal to each of a second group of gate lines among the plurality of gate lines GL. The light emission control driving circuit 230 may include a plurality of light emission control stages configured to supply a light emission control signal to each of a third group of gate lines among the plurality of gate lines GL.

The number of gate lines, the number of scan driving circuits, and the number of light emission control driving circuits connected to the subpixels P of each pixel line are not limited to those shown in FIG. 1, and may vary depending on the detailed configuration of the pixel circuit constituting each subpixel P.

The data driving circuit 410 may be configured to convert digital data supplied from a timing controller into an analog data voltage and supply the data voltage to each of a plurality of data lines DL of the display panel 100. The data driving circuit 410 includes at least one data driving integrated circuit (IC). The at least one data driving IC may be mounted on each circuit film 420 and electrically connected to a pad area arranged in a bezel area BZ4 of the display panel 100 via an anisotropic conductive film (ACF). The circuit film 420 may be any one of a chip on Film (COF), a flexible printed circuit (FPC), and a flexible flat cable (FPC).

Thin film transistors included in the driving circuit arranged in the display area DA and the bezel area BZ1 to BZ4 of the display panel 100 may use any one of a polysilicon semiconductor, an amorphous silicon semiconductor, and an oxide semiconductor. In one embodiment, the thin film transistors of the display panel 100 may include at least one of a low temperature polysilicon (LTPS) transistor and an oxide transistor using a metal oxide semiconductor.

According to one embodiment of the present specification, when an open defect occurs in a data line DL, a plurality of redundancy lines and a low potential power line adjacent to an open portion of the data line may be divided into a plurality of parts. The divided redundancy lines and the divided first low-potential power lines and the divided data lines may be electrically connected at each intersection through a repair process, thereby repairing the open defect in the data line. A detailed description thereof will be given later.

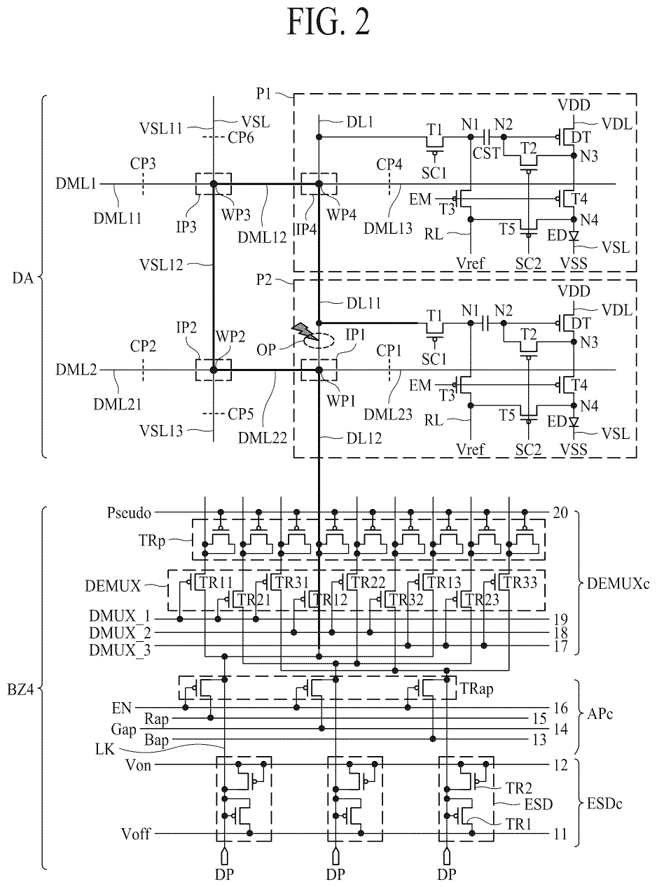

FIG. 2 is a drawing illustrating a repair structure of a data line in a display device according to one embodiment of the present disclosure.

Referring to FIGS. 1 and 2, a display device according to one embodiment may include a driving circuit area disposed in a bezel area BZ4 of a display panel 100 and a plurality of subpixels P1 and P2 disposed in a display area DA of the display panel 100.

The bezel area BZ4 of the display panel 100 may include an electrostatic discharge protection circuit area ESDc, a lighting inspection circuit area APc, and a demultiplexer circuit area DEMUXc disposed in a vertical direction (a first direction or a Y direction) between the pad area, where the data pads DP are disposed in, and the display area DA.

The data pads DP disposed in the pad area may be connected to a data driving circuit 410 via a circuit film 410, and may be configured to receive data signals from the data driving circuit 410 and output them to data links LK.

The electrostatic protection circuit area ESDc may include a plurality of electrostatic protection circuits ESD respectively connected to the data link lines LK and commonly connected to the power lines 11 and 12. Each of the plurality of electrostatic protection circuits ESD may include a transistor TR1 connected in a diode structure between the data link line LK and a power line 11 to which a gate off voltage Voff is applied, and a transistor TR2 connected in a diode structure between the power line 12 to which a gate on voltage Von is applied and each data link line. The plurality of electrostatic protection circuits ESD may be configured to operate when static electricity is introduced through the data link lines to discharge the static electricity through the power line 11.

The lighting inspection circuit area APc may include a plurality of inspection transistors TRap respectively connected to data link lines LK. The plurality of inspection transistors TRap may be commonly connected to a control line 16 to which an enable signal EN is applied, and may be individually connected between inspection signal supply lines 13, 14, and 15 and the data link lines. The inspection signal supply lines 13, 14, and 15 may supply inspection signals Rap, Gap, and Bap respectively when the lighting inspection is performed.

A plurality of demultiplexer circuits DEMUX disposed in a demultiplexer circuit area DEMUXc may distribute and apply data signals supplied through data link lines LK to data lines DL greater than the number of data link lines LK. The demultiplexer circuit DEMUX may include transistors TR11 to TR13, TR21 to TR23, and TR31 to TR33 connected to a plurality of control lines 17, 18, and 19 to which a plurality of control signals DMUX_1, DMUX_2, and DMUX_3 are respectively applied.

For example, the demultiplexer circuit DEMUX may time-divide the R data signals supplied through the first data link line to sequentially supply the time-divided R data signals to three data lines. The demultiplexer circuit DEMUX may time-divide G data signals supplied through the second data link line sequentially supply the time-divided G data signals to three data lines. The demultiplexer circuit DEMUX may time-divide B data signals supplied through the third data link line and sequentially supply the time-divided B data signals to three data lines.

The demultiplexer circuit area DEMUXc may further include a plurality of pseudo transistors TRp. The plurality of pseudo transistors TRp may be configured to be controlled by a pseudo signal line 20 to which a pseudo signal Pesudo is applied to be connected to each of a plurality of data lines DL, thereby reducing electromagnetic interference noise. The pseudo signal line 20 may supply a pseudo signal Pesudo that has a phase opposite to a phase of at least one of a plurality of control signals DMUX_1, DMUX_2, and DMUX_3 applied to the demultiplexer circuit DEMUX.

The bezel area BZ1 to BZ4 of the display panel 100 may include a high-potential power supply line that is commonly connected to a plurality of high-potential power lines VDL of the display area DA to supply a high-potential power voltage VDD, and a low-potential power supply line that is commonly connected to a plurality of low-potential power lines VSL of the display area DA to supply a low-potential power voltage VSS.

The display area DA may include a data line DL1 extending in the vertical direction (Y axis direction or a first direction) and a low-potential power line VSL, redundancy lines DML1, DML2 extending in the horizontal direction (a second direction or an X axis direction), and subpixels P1, P2 connected to the data line DL1 and arranged in the vertical direction.

Each of the subpixels P1, P2 may include a light emitting element ED and a pixel circuit that are independently configured to drive the light emitting element ED. The pixel circuit may include a driving thin film transistor DT and a plurality of thin film transistors T1 to T5 and a storage capacitor Cst.

Each of the thin film transistors DT, T1 to T5 of the pixel circuit may use any one of polysilicon semiconductors, amorphous silicon semiconductors, and oxide semiconductors.

The first thin film transistor T1 (a switching transistor) may be configured to be controlled by a first scan signal SC1 to connect a first node N1 connected to a data line DL1 and a first electrode of a storage capacitor Cst. The first thin film transistor T1 may be turned on by a gate on voltage of the first scan signal SC1 supplied through the first gate line and may be configured to apply a data voltage Vdata supplied through the data line DL1 to the storage capacitor Cst during a data programming period.

The second thin film transistor T2 (a sampling transistor) may be configured to be controlled by a second scan signal SC2 to connect a second node N2 connected to a gate electrode of a driving transistor DT, and a third node N3 connected to a drain electrode second electrode of the driving transistor DT. The second thin film transistor T2 may be turned on by a gate on voltage of the second scan signal SC2 supplied through the second gate line and may be configured to connect the gate electrode and the drain electrode of the driving transistor DT during a sampling period. The second thin film transistor T2 may be configured to sample a threshold voltage of the driving transistor DT by connecting the driving transistor DT in a diode structure during the sampling period and charge the storage capacitor Cst.

The third thin film transistor T3 (a first initialization transistor) may be configured to controlled by an emission control signal EM to connect to a reference line RL supplying a reference voltage Vref and the first node N1 of the storage capacitor Cst. The third thin film transistor T3 may be turned on by a gate on voltage of the emission control signal EM supplied through the third gate line and may be configured to apply the reference voltage Vref to the first node N1 of the storage capacitor Cst during an emission period.

The fourth thin film transistor T4 (an emission control transistor) may be configured to controlled by a light emission control signal EM to connect a third node N3 of a driving transistor DT and a fourth node N4 connected to an anode electrode of a light emitting element ED. The fourth thin film transistor T4 may be turned on by a gate on voltage of the light emission control signal EM supplied through a third gate line and may be configured to connect the third node N3 of the driving transistor DT and the anode electrode of the light emitting element ED during a light emission period.

The fifth thin film transistor T5 (a second initialization transistor) may be configured to controlled by the second scan signal SC2 to connect the fourth node N4 connected to the reference line RL and the anode of the light emitting element ED. The fifth thin film transistor T5 may be turned on by the gate on voltage of the second scan signal SC2 supplied through the second gate line and may be configured to apply the reference voltage Vref to the fourth node N4 connected to the anode electrode of the light emitting element ED during the sampling period.

The storage capacitor Cst may be connected to a first node N1 and a second node N2 connected to a gate electrode of a driving transistor DT. The storage capacitor Cst may charge a data voltage Vdata compensated for by a driving transistor Vth. The storage capacitor Cst may hold the charged voltage and apply the held voltage as a driving voltage to a gate electrode of the driving transistor DT.

The driving transistor DT may have a gate electrode connected to a second node N2, a source electrode (first electrode) connected to a high-potential power line VDL, and a drain electrode (second electrode) connected to a third node N3. The driving transistor DT may be configured to control a driving current according to a voltage charged in a storage capacitor Cst, to supply the driving current to a light emitting element ED through a fourth thin film transistor T4, thereby controlling the light emitting intensity of the light emitting element OLED.

The light emitting element ED may have an anode connected to a fourth node N4 of a fourth thin film transistor T4, a cathode connected to a low-potential power line VSL, and an organic light emitting layer between the anode and the cathode. The light emitting element ED may generate light having a brightness proportional to the amount of driving current supplied from a driving transistor DT through the fourth thin film transistor T4.

Referring to FIGS. 1 and 2, the first gate line may be configured to receive a first scan signal SC1 from the first scan driving circuit 210, the second gate line may be configured to receive a second scan signal SC2 from the second scan driving circuit 220, and the third gate line may be configured to receive an emission control signal EM from the emission control driving circuit 230.

A first redundancy line DML1 and a second redundancy line DML2 may extend in the horizontal direction (X axis direction or a second direction) via the first and second subpixels P1 and P2, respectively.

The second redundancy line DML2 may intersect a first data line DL1 at a first intersection IP1 and a first low-potential power line VSL1 at a second intersection IP2. The first redundancy line DML1 may intersect a first low-potential power line VSL1 at a third intersection IP3 and the first data line DL1 at a fourth intersection IP4.

An open defect of the first data line DL1 may occur between the first intersection IP1 and the fourth intersection IP4, and the first data line DL1 may be divided into a 1-1 data line DL11 and a 1-2 data line DL12 based on an open portion OP of the first data line DL1.

The second redundancy line DML2 may be divided into 2-1, 2-2, and 2-3 redundancy lines DML21, DML22, and DML23 by a first and a second cutting parts CP1 and CP2 to which the laser beam is irradiated, respectively. The first cutting part CP1 may be disposed on the right side of the first intersection portion IP1, and the second cutting part CP2 may be disposed on the left side of the second intersection portion IP2.

The first redundancy line DML1 may be divided into 1-1, 1-2, and 1-3 redundancy lines DML11, DML12, and DML13 by a third and a fourth cutting parts CP3 and CP4 to which the laser beam is irradiated, respectively. The third cutting part CP3 may be disposed on the left side of the third intersection portion IP3, and the fourth cutting part CP4 may be disposed on the right side of the fourth intersection portion IP4.

The first low-potential power line VSL may be divided into 1-1, 1-2, and 1-3 low-potential power lines VSL11, VSL12, and VSL13 by a fifth and a sixth cutting parts CP5 and CP6 to which the laser beam is irradiated, respectively. The fifth cutting part CP5 may be disposed below the second intersection portion IP2, and the sixth cutting part CP4 may be disposed above the third intersection portion IP3.

Each of the first to fourth intersections IP1 to IP4 may include a first to a fourth repair part WP1 to WP4 welded by a laser welding method.

At the first intersection IP1, the 1-2 data line DL12 and the 2-2 redundancy line DML22 may be connected through a first repair part WP1. At the second intersection IP2, the 1-2 low-potential power line VSL12 and the 2-2 redundancy line DML22 may be connected through a second repair part WP2. At a third intersection IP3, the 1-2 low-potential power line VSL12 and the 1-2 redundancy line DML12 may be connected through the fourth repair part WP4. At a fourth intersection IP4, the 1-1 data line DL11 and the 1-2 redundancy line DML12 may be connected through the fourth repair part WP4.

Accordingly, the 1-2 data line DL12 may be electrically connected to the 1-1 data line DL11 through a repair path that passes through the first repair part WP1, the 2-2 redundancy line DML22, the second repair part WP2, the 1-2 low-potential power line VSL12, the third repair part WP3, the 1-2 redundancy line DML12, and the fourth repair part WP4.

The data voltage Vdata applied from a data driving circuit to the 1-2 data line DL12 via the bezel area BZ4 may be applied to the 1-1 data line DL11 via a repair path that passes through the first repair part WP1, the 2-2 redundancy line DML22, the second repair part WP2, the 1-2 low-potential power line VSL12, the third repair part WP3, the 1-2 redundancy line DML12, and the fourth repair part WP4.

Accordingly, the first and second subpixels P1, P2 can receive data voltage Vdata through the repaired data lines DL11, DL12 and operate normally, so that pixel defects can be prevented through the repair process even if an open defect occurs in the data line DL1.

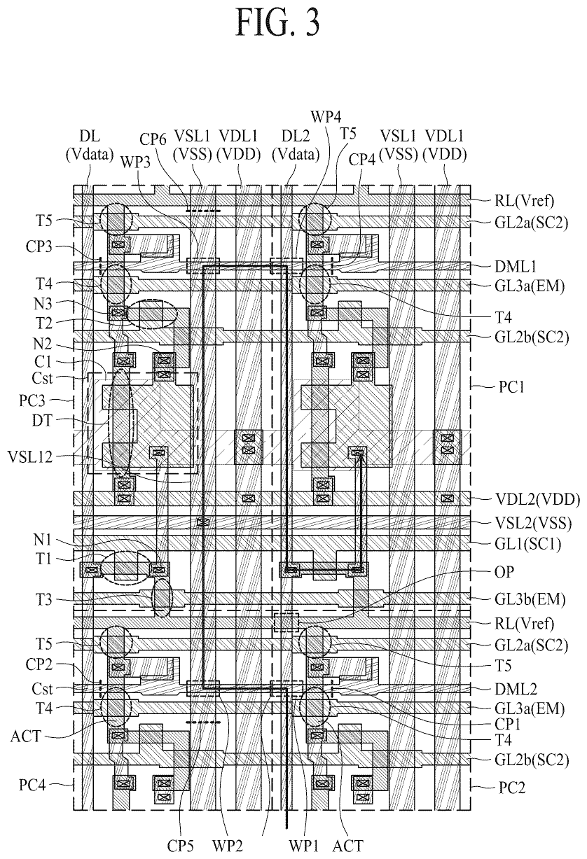

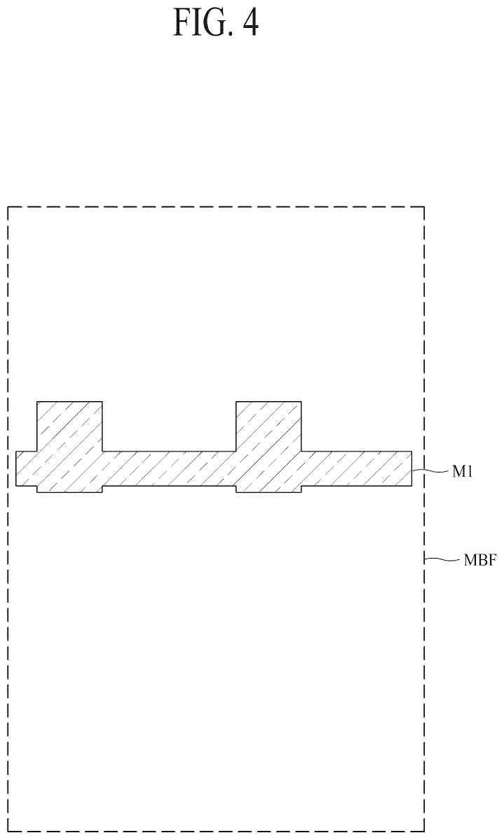

FIG. 3 is a drawing illustrating a layout structure of pixel circuits including a repair structure of a data line in a display device according to one embodiment of the present disclosure, and FIGS. 4, 5A, 5B, 6A, 6B, 7A, 7B, 8A, 8B, 9A, 9B, 10A, and 10B are drawings illustrating the layout of the pixel circuits illustrated in FIG. 3 according to each mask process according to one embodiment of the present disclosure.

Specifically, FIG. 3 illustrates the layout of the first metal layer lower metal layer, the active layer, the second metal layer gate metal layer, the third metal layer upper metal layer, and the fourth metal layer source/drain metal layer of the pixel circuits.

Referring to FIG. 3, each of the pixel circuits PC1, PC2, PC3, and PC4 may include the driving transistor DT and the plurality of thin film transistors T1 to T5 and the storage capacitor Cst. The pixel circuits PC2 and PC4 may be disposed closer to the driving circuit area of the bezel B4 shown in FIG. 2 than the pixel circuits PC1 and PC3.

The reference line RL configured to supply a reference voltage Vref, a 2-1 gate line GL2a configured to supply a second scan signal SC2, a 3-1 gate line GL3a[n] configured to supply an emission control signal EM, a 2-2 gate line GL2b configured to supply a second scan signal SC2, a second high-potential power line VDL2 configured to supply a high-potential power voltage VDD, a second low-potential power line VSL2 configured to supply a low-potential power voltage VSS, a first gate line GL1 configured to supply a first scan signal SC1, and a 3-2 gate line GL3b configured to supply an emission control signal EM may be arranged to be extended in the horizontal direction (X axis direction or a second direction) and be spaced apart in the vertical direction (Y axis direction or a first direction).

A data line DL1 configured to supply a data voltage Vdata, a first high-potential power line VDL1, and a first low-potential power line VSL1 may be arranged to extend in the vertical direction and be spaced apart in the horizontal direction.

The redundancy line DML1 may be disposed between the 2-1 gate line GL2a and the 3-1 gate line GL3a.

Referring to FIGS. 3 and 4, a first capacitor electrode of the storage capacitor Cst may be formed of a first metal layer (a lower metal layer) M1. The first metal layer M1 may be disposed on a multi-buffer layer MBF on a substrate.

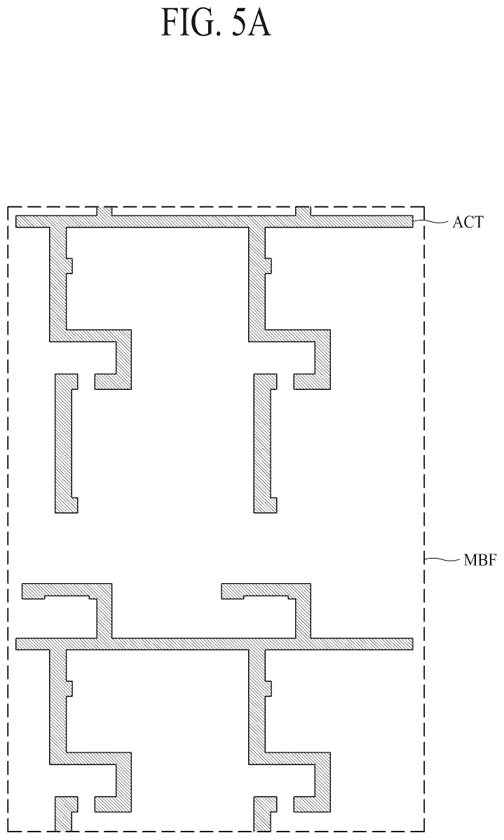

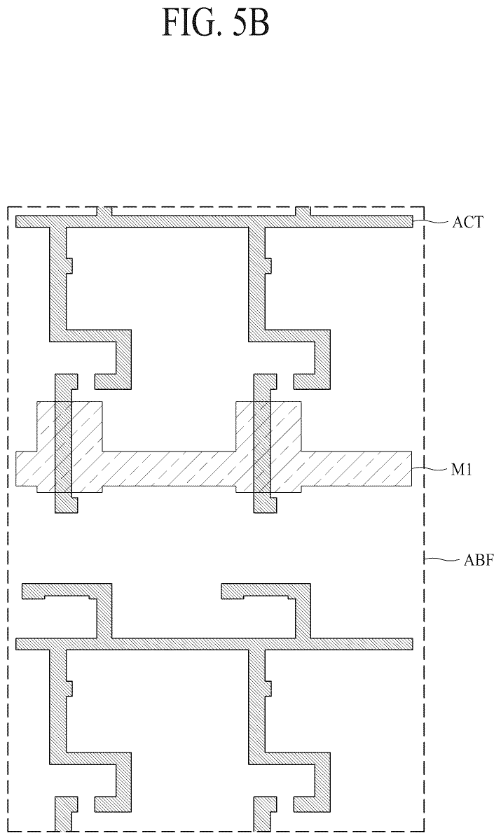

Referring to FIG. 3 and FIGS. 5A and 5B, in each pixel circuit, the driving transistor DT and the plurality of thin film transistors T1 to T5 may include an active layer ACT formed of LTPS. The active layer ACT may include a channel of each of the thin film transistors DT and T1 to T5 having semiconductor characteristics, and a source electrode and a drain electrode of each of the thin film transistors DT and T1 to T5 having conductive characteristics. The active layer ACT may further include a reference line RL formed as a conductive region. The active layer ACT may be disposed on an active buffer layer ABF covering the first metal layer M1.

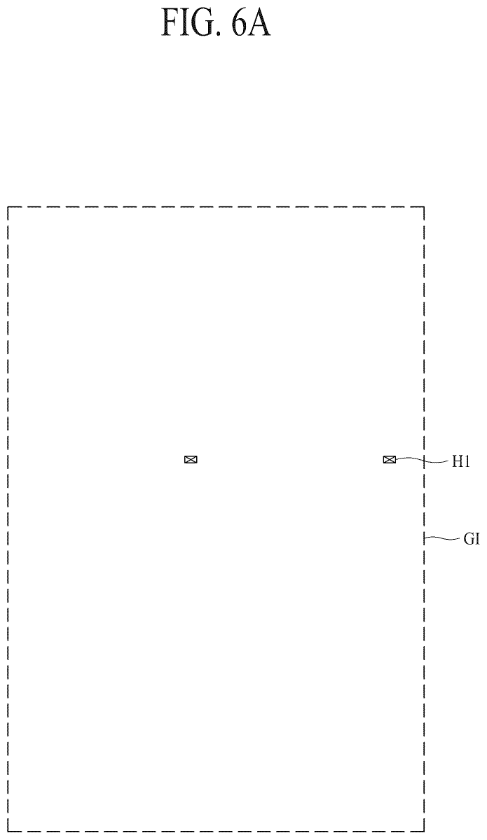

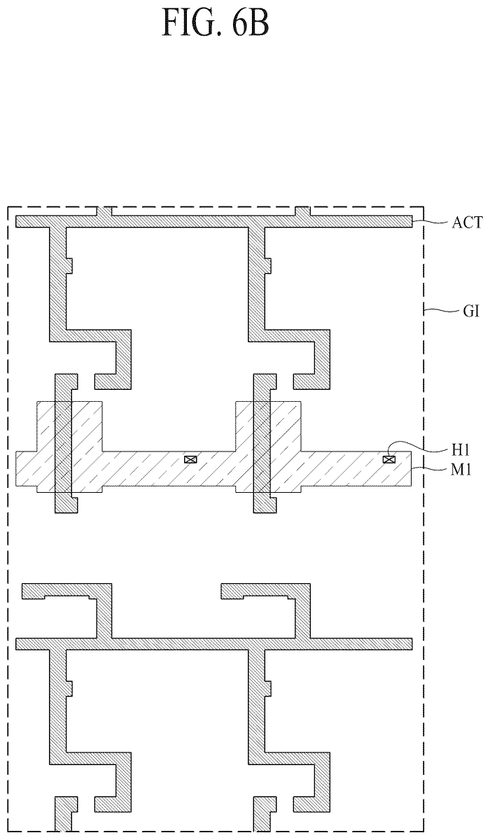

Referring to FIGS. 6A and 6B, a gate insulating layer GI covering the active layer ACT may be disposed on the active buffer layer ABF and contact holes H1 exposing the first metal layer M1 may be formed by penetrating the active buffer layer ABF and the gate insulating layer GI.

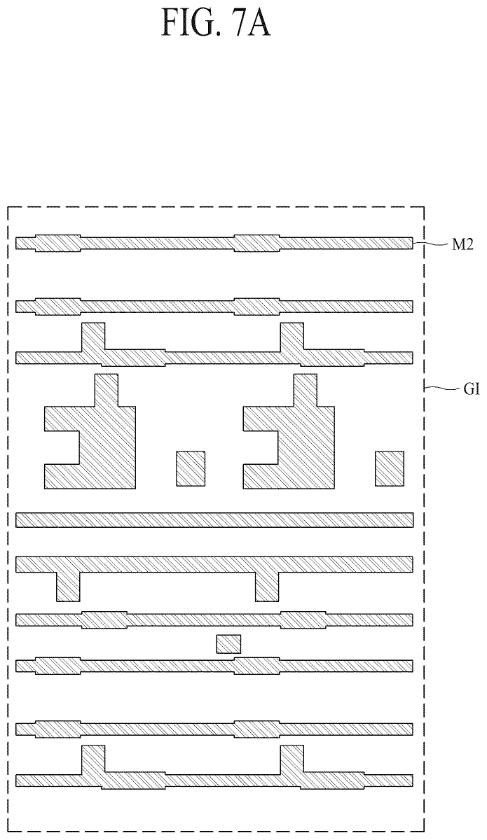

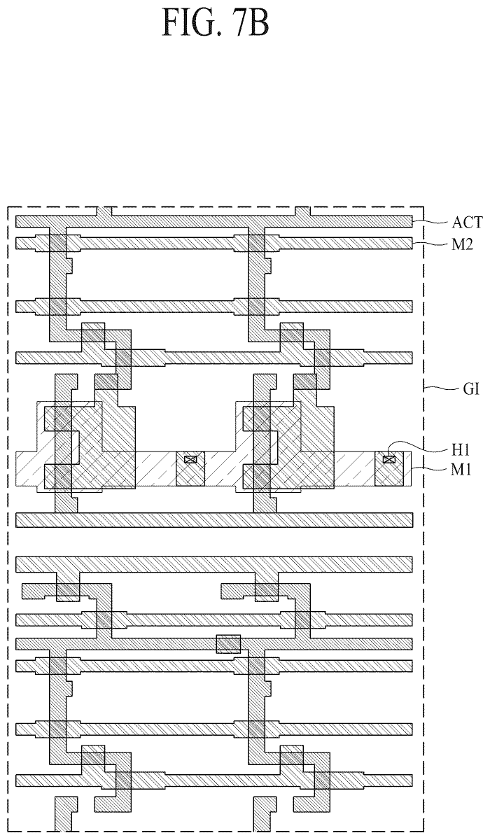

Referring to FIG. 3 and FIGS. 7A and 7B, a gate electrode of the driving transistor DT, a second capacitor electrode of the storage capacitor Cst, a gate electrode of the fifth thin film transistor T5 and the 2-1 gate line GL2a, the 3-1 gate line GL3a including a gate electrode of the fourth thin film transistor T4, a gate electrode of the second thin film transistor T2 and the 2-2 gate line GL2b, the second low-potential power line VSL2, a gate electrode of the first thin film transistor T1 and the first gate line GL1, and the 3-2 gate line GL3b including a gate electrode of the third thin film transistor T3 may be formed of a second metal layer (a gate metal layer) M2. The second metal layer M2 may be disposed on a gate insulating layer GI covering an active layer ACT.

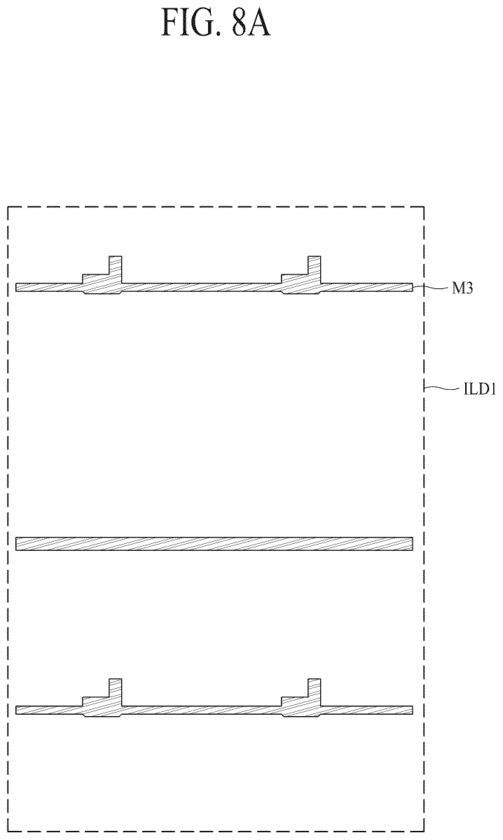

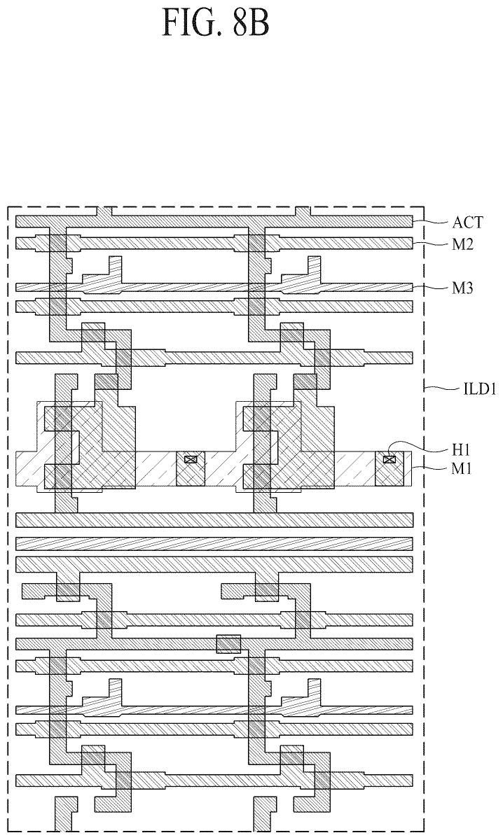

Referring to FIG. 3, FIG. 8A, and FIG. 8B, the redundancy lines DML1, DML2 and the second high-potential power line VDL2 may be formed of a third metal layer (an upper metal layer) M3. The third metal layer M3 may be disposed on a first interlayer insulating layer ILD1 covering the second metal layer M2.

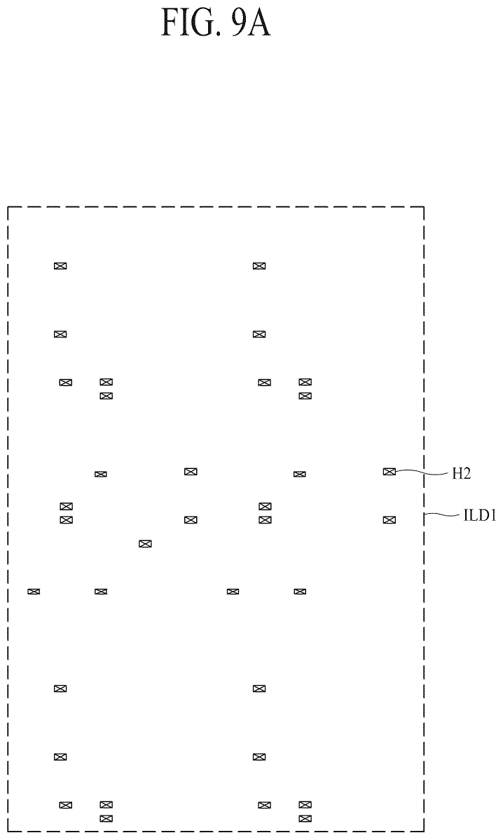

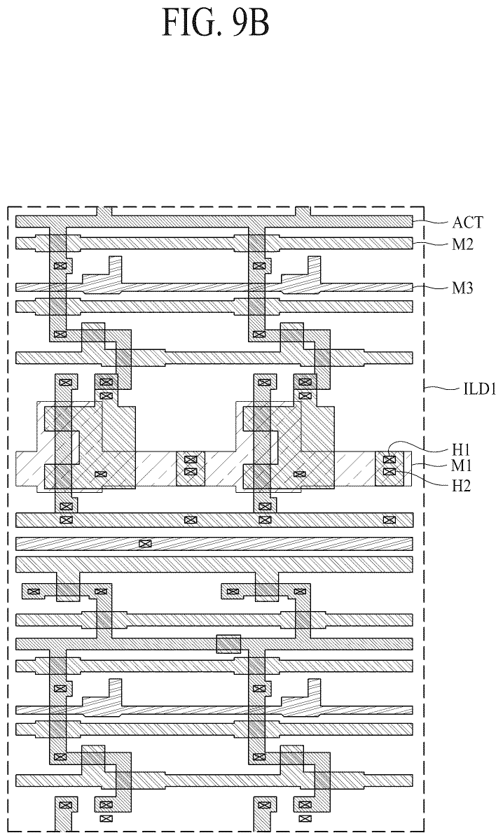

Referring to FIG. 9A and FIG. 9B, contact holes H2 penetrating the first interlayer insulating layer ILD1 and contact holes H2 penetrating the first interlayer insulating layer ILD1 and the gate insulating layer GI may be formed.

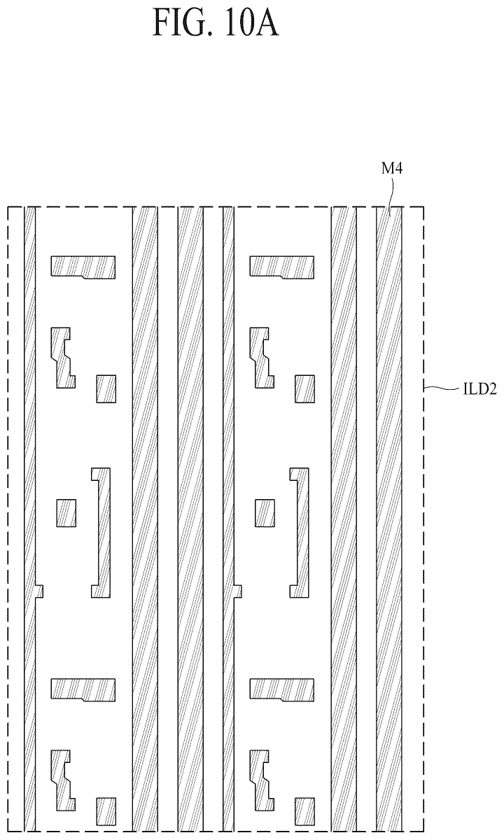

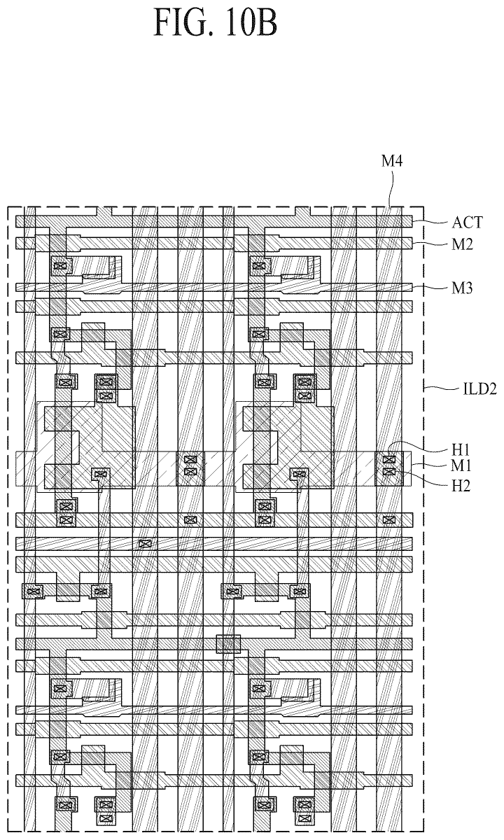

Referring to FIG. 3, FIG. 10A, and FIG. 10B, the data line DL1, the first high-potential power line VDL1, and the first low-potential power line VSL1 may be formed of a fourth metal layer (a source-drain metal layer) M4. The fourth metal layer M4 may be disposed on a second interlayer insulating layer ILD2 covering the third metal layer M3.

Referring to FIG. 3, the second redundancy line DML2 may intersect the first data line DL1 at the first intersection IP1 and the first low-potential power line VSL1 at the second intersection IP2. The first redundancy line DML1 may intersect the first low-potential power line VSL1 at the third intersection IP3 and the first data line DL1 at the fourth intersection IP4.

The defect in which the first data line DL1 is opened between the first intersection IP1 and the fourth intersection IP4 may occur, and the first data line DL1 may be divided into the 1-1 data line DL11 and the 1-2 data line DL12 based on the open portion OP.

The second redundancy line DML2 may be divided into the 2-1, 2-2, and 2-3 redundancy lines DML21, DML22, and DML23 by the first and second cutting parts CP1 and CP2, respectively.

The first cutting part CP1 of the second redundancy line DML2 may be located to the right of the semiconductor layer ACT shared by the fourth and the fifth thin film transistor T4 and T5 in the second pixel circuit PC2 located to the right of the first intersection portion IP1. The 1-2 data line DL12 and the 2-2 redundancy line DML22 may intersect and overlap at the first intersection IP1.

The second cutting part CP2 of the second redundancy line DML2 may be disposed on the left side of the semiconductor layer ACT shared by the fourth and the fifth thin film transistor T4 and T5 in the fourth pixel circuit PC4 disposed on the left side of the second intersection IP2. The 1-2 low-potential power line VSL12 and the 2-2 redundancy line DML22 may intersect and overlap at the second intersection IP2.

The first redundancy line DML1 may be divided into the 1-1, 1-2, and 1-3 redundancy lines DML11, DML12 and DML13 by the third and fourth cutting parts CP3 and CP4, respectively.

The third cutting part CP3 of the first redundancy line DML1 may be disposed on the left side of the semiconductor layer ACT shared by the fourth and the fifth thin film transistor T4 and T5 in the third pixel circuit PC3 disposed on the left side of the third intersection IP3. The 1-2 low-potential power line VSL12 and the 1-2 redundancy line DML12 may intersect and overlap at the third intersection IP3.

The fourth cutting part CP4 of the first redundancy line DML1 may be located to the right of the semiconductor layer ACT shared by the fourth and the fifth thin film transistor T4 and T5 in the first pixel circuit PC1 located to the right of the fourth intersection portion IP4. The 1-1 data line DL11 and the 1-2 redundancy line DML12 may intersect and overlap at the fourth intersection portion IP4.

The first low-potential power line VSL1 may be divided into 1-1, 1-2, and 1-3 low-potential power lines VSL11, VSL12, and VSL13 by a fifth and a sixth cutting parts CP5 and CP6 to which the laser beam is irradiated, respectively.

The fifth cutting part CP5 of the first low-potential power line VSL1 may be disposed below the 3-1 gate line GL3a adjacent to the second intersection portion IP2, that is, between the 3-1 gate line GL3a and the 2-2 gate line GL2b in the fourth pixel circuit PC4.

The sixth cutting part CP4 of the first low-potential power line VSL1 may be disposed above the 2-1 gate line GL2 a adjacent to the third intersection portion IP3, that is, between the reference line RL and the 2-1 gate line GL2a in the third pixel circuit PC3.

Each of the first to fourth intersections IP1, IP2, IP3 and IP4 may include each of first to fourth repair parts WP1 to WP4 welded by a laser welding method.

At the first intersection IP1, the 1-2 data line DL12 and the 2-2 redundancy line DML22 may be connected through the first repair part WP1. At the second intersection IP2, the 1-2 low-potential power line VSL12 and the 2-2 redundancy line DML22 may be connected through the second repair part WP2. At the third intersection IP3, the 1-2 low-potential power line VSL12 and the 1-2 redundancy line DML12 may be connected through the fourth repair part WP4. At the fourth intersection IP4, the 1-1 data line DL11 and the 1-2 redundancy line DML12 may be connected through the fourth repair part WP4.

Accordingly, the 1-2 data line DL12 may be electrically connected to the 1-1 data line DL11 through a repair path that passes through the first repair part WP1, the 2-2 redundancy line DML22, the second repair part WP2, the 1-2 low-potential power line VSL12, the third repair part WP3, the 1-2 redundancy line DML12, and the fourth repair part WP4.

The data voltage Vdata applied from a data driving circuit to a 1-2 data line DL12 may be applied to a 1-1 data line DL11 through a repair path that passes through a first repair part WP1, a 2-2 redundancy line DML22, a second repair part WP2, a 1-2 low-potential power line VSL12, a third repair part WP3, a 1-2 redundancy line DML12, and a fourth repair part WP4.

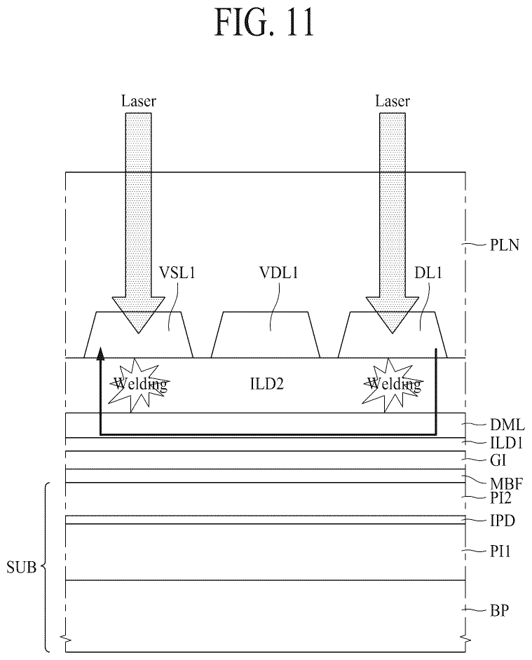

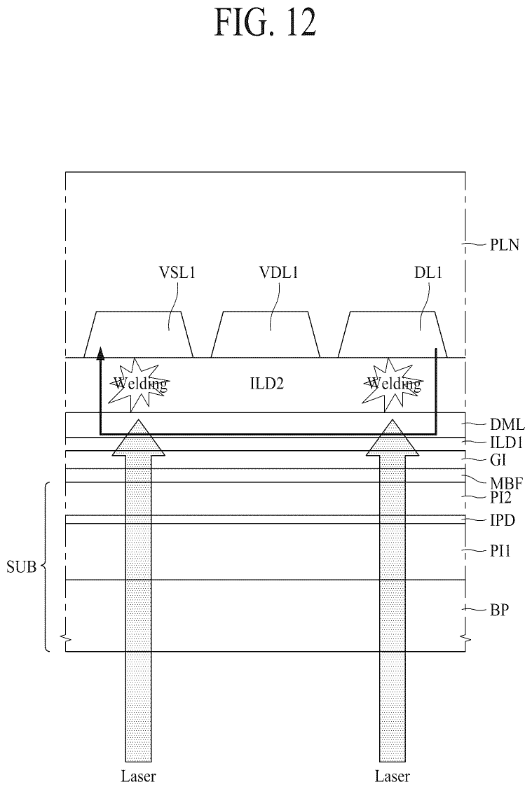

FIG. 11 is a drawing illustrating a repair process of a display device according to one embodiment of the present disclosure and FIG. 12 is a drawing illustrating a repair process of a display device according to one embodiment of the present disclosure.

Referring to FIGS. 11 and 12, a plurality of insulating layers MBF, GI and ILD1 may be disposed on a substrate SUB, and a redundancy line DML may be disposed on a first interlayer insulating layer ILD1. The substrate SUB may include a base substrate BP, first and second resin substrates PI1, PI2, and an interlayer insulating layer IPD between the first and second resin substrates PI1, PI2.

A second interlayer insulating layer ILD2 covering the redundancy line DML may be disposed on the first interlayer insulating layer ILD1. A data line DL1, a first high-potential power line VDL1, and a first low-potential power line VSL1 may be disposed on the second interlayer insulating layer ILD2. A planarization layer PLN covering the data line DL1, the first high-potential power line VDL1, and the first low-potential power line VSL1 may be disposed on the second interlayer insulating layer ILD2.

Referring to FIG. 11, after completing the process of forming the data line DL1, the first high-potential power line VDL1, and the first low-potential power line VSL1 with source-drain metal layers, an open defect in each of the data lines may be detected through an electrical application inspection.

When an open defect of the data line DL1 is detected, the redundancy line DML and the first low-potential power line VSL1 may be divided into a plurality of parts by a laser cutting method. Then, the data line DL1 and the redundancy line DML may be electrically connected at the intersection by a laser welding method in which a laser is irradiated from above, and the first low-potential power line VSL1 and the redundancy line DML may be electrically connected at the intersection of the first low-potential power line VSL1 and the redundancy line DML. Accordingly, the open defect of the data line DL1 may be repaired.

Referring to FIG. 12, the display device according to one embodiment may detect a data line defect in an inspection process after attachment to a printed circuit board.

When an open defect of a data line is detected, the redundancy line DML and the first low-potential power line VSL1 may be divided into a plurality of parts by a laser cutting method. Then, the data line DL1 and the redundancy line DML are electrically connected at the intersection by a laser welding method in which a laser is irradiated from below, and the first low-potential power line VSL1 and the redundancy dummy line DML are electrically connected at the intersection of the first low-potential power line VSL1 and the redundancy dummy line DML, thereby repairing the data line open defect.

As described above, in the display device according to one embodiment of the present disclosure, when an open defect occurs in the first data line, the first and second redundancy lines and the first low-potential power line adjacent to the open portion of the first data line are each divided into a plurality of parts, and the divided first and second redundancy lines, the divided first low-potential power line, and the divided data line are electrically connected at each intersection through a repair process, thereby repairing the open defect in the first data line.

A display device according to one embodiment of the present specification may repair and use a display panel in which an open defect has occurred in a data line, thereby reducing manufacturing costs.

The display device according to one or more embodiments of the present disclosure may be applied to various electronic devices. For example, the display device according to one or more embodiments of the present disclosure may be applied to a mobile device, a video phone, a smart watch, a watch phone, a wearable device, a foldable device, a rollable device, a bendable device, a flexible device, a curved device, an electronic diary, electronic book, a portable multimedia player (PMP), a personal digital assistant(PDA), MP3 player, a mobile medical device, a desktop PC, a laptop PC, a netbook computer, a workstation, a navigator, a vehicle navigator, a vehicle display device, a television, a wall paper display device, a signage device, a game device, a notebook computer, a monitor, a camera, a camcorder, and home appliances.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that the present disclosure described above is not limited by the above-described embodiments and the accompanying drawings and that various substitutions, modifications and variations may be made in the present disclosure without departing from the scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a plurality of subpixels in a display area;
a plurality of data lines connected to the plurality of subpixels;
a plurality of low-potential power lines connected to the plurality of subpixels; and
a plurality of redundancy lines crossing the plurality of data lines and the plurality of low-potential power lines,
wherein the plurality of subpixels include a first subpixel and a second subpixel adjacent to each other in a first direction and connected to a first data line from the plurality of data lines, the first data line extending in the first direction,
wherein the plurality of low-potential power lines include a first low-potential power line parallel to the first data line in a second direction,
wherein the plurality of redundancy lines include a first redundancy line and a second redundancy line extended in the second direction and respectively passing through the first subpixel and the second subpixel,
wherein the second redundancy line intersects the first data line at a first intersection and intersects the first low-potential power line at a second intersection, and
wherein the first redundancy line intersects the first low-potential power line at a third intersection and intersects the first data line at a fourth intersection.

2. The display device of claim 1, wherein:
when the first data line is opened between the first intersection and the fourth intersection, the first data line is divided into a 1-1 data line and a 1-2 data line,
the second redundancy line is divided into a 2-1 redundancy line, a 2-2 redundancy line, and a 2-3 redundancy line by a first cutting part and a second cutting part,
the first redundancy line is divided into a 1-1 redundancy line, a 1-2 redundancy line, and a 1-3 redundancy line by a third cutting part and a fourth cutting part, and
the first low-potential power line is divided into a 1-1 low-potential power line, a 1-2 low-potential power line, and a 1-3 low-potential power line by a fifth cutting part and a sixth cutting part.

3. The display device of claim 2, wherein:
the 2-2 redundancy line is connected to the 1-2 data line via a first repair part at the first intersection and connected to the 1-2 low-potential power line via a second repair part at the second intersection, and
the 1-2 redundancy line is connected to the 1-2 low-potential power line via a third repair part at the third intersection and connected to the 1-2 data line via a fourth repair part at the fourth intersection.

4. The display device of claim 3, wherein a data signal applied to the 1-2 data line is applied to the 1-1 data line via the first repair part, the 2-2 redundancy line, the second repair part, the 1-2 low-potential power line, the third repair part, the 1-2 redundancy line, and the fourth repair part.

5. The display device of claim 2, wherein the first redundancy line and the second redundancy line are on a first interlayer insulating layer, and the first data line and the first low-potential power line are on a second interlayer insulating layer covering the first redundancy line and the second redundancy line.

6. The display device of claim 5, wherein the first cutting part is at a first side of the first intersection, the second cutting part is at a second side of the second intersection, the third cutting part is at a second side of the third intersection, and the fourth cutting part is at a first side of the fourth intersection.

7. The display device of claim 3, wherein each of a first pixel circuit and a second pixel circuit include a plurality of horizontal signal lines extending in the second direction and spaced apart in the first direction,
wherein the plurality of horizontal signal lines comprise:
a 2-1 gate line configured to supply a second scan signal,
a 3-1 gate line configured to supply a light emission control signal,
a 2-2 gate line configured to supply the second scan signal,
a second high-potential power line configured to supply a high-potential power voltage,
a second low-potential power line configured to supply a low-potential power voltage,
a first gate line configured to supply a first scan signal, and
a 3-2 gate line configured to supply the light emission control signal.

8. The display device of claim 7, wherein the first redundancy line is between the 2-1 gate line and the 3-1 gate line of the first pixel circuit, and the second redundancy line is between the 2-1 gate line and the 3-1 gate line of the second pixel circuit.

9. The display device of claim 7, wherein the 2-1 gate line, the 3-1 gate line, the 2-2 gate line, the second low-potential power line, the first gate line, and the 3-2 gate line are on a gate insulating layer.

10. The display device of claim 7, wherein the first redundancy line, the second redundancy line, and the second high-potential power line are on a first interlayer insulating layer above a gate metal layer.

11. The display device of claim 5, further comprising:
a first high-potential power line between the first low-potential power line and the first data line.

12. The display device of claim 7, wherein each of a plurality of pixel circuit includes:
a driving transistor connected to a light emitting element;
an emission control transistor configured to connect the driving transistor and the light emitting element; and
an initialization transistor configured to supply a reference voltage to an anode electrode of the light emitting element.

13. The display device of claim 12, wherein:
the first cutting part of the second redundancy line is on a right side adjacent to a second semiconductor layer shared by an emission control transistor and an initialization transistor in the second pixel circuit, and
the second semiconductor layer is on the right side of the first intersection.

14. The display device of claim 12, wherein:
the second cutting part of the second redundancy line is on a left side adjacent to a fourth semiconductor layer shared by an emission control transistor and an initialization transistor in a fourth pixel circuit, the fourth pixel circuit on a left side adjacent to the second pixel circuit, and
the fourth semiconductor layer is on the left side of the second intersection.

15. The display device of claim 14, wherein:
the third cutting part of the first redundancy line is on a left side adjacent to a third semiconductor layer shared by an emission control transistor and an initialization transistor in a third pixel circuit, the third pixel circuit on a left side adjacent to the first pixel circuit, and
the third semiconductor layer is on the left side of the third intersection.

16. The display device of claim 12, wherein:
the fourth cutting part of the first redundancy line is on a right side adjacent to a first semiconductor layer shared by an emission control transistor and an initialization transistor in the first pixel circuit, and
the first semiconductor layer is on the right side of the fourth intersection.

17. The display device of claim 15, wherein the fifth cutting part of the first low-potential power line is below a gate line adjacent to the second intersection in the fourth pixel circuit.

18. The display device of claim 15, wherein the sixth cutting part of the first low-potential power line is above a gate line adjacent to the third intersection in the third pixel circuit.

19. The display device of claim 7, wherein the second pixel circuit is closer to a driving circuit area than the first pixel circuit.

20. The display device of claim 15, wherein the fourth pixel circuit is closer to a driving circuit area than the third pixel circuit.
